(19) United States
(12) Patent Application Publication
(10) Pub. No.: US 2008/0273410 A1
(43) Pub. Date: Nov. 6, 2008

(54) Tungsten digitlines

(76) Inventor: Jaydeb Goswami, Boise, ID (US)

Correspondence Address: BROOKS, CAMERON & HUEBSCH , PLLC, 1221 NICOLLET AVENUE, SUITE 500, MINNEAPOLIS, MN, 55403, US

(21) Appl. No.: 11/800,199

(22) Filed: May 4, 2007

(51) Int. Cl. G11C 7/00; H01L 21/4763; H01L 27/108

(52) U.S. Cl. 365/222; 257/208; 438/648; 257/E27.084; 257/E21.495

(57) ABSTRACT

Methods, devices, and systems for using and forming tungsten digitlines have been described. The tungsten digitlines formed according to embodiments of the present disclosure can be formed with a tungsten (W) monolayer on a tungsten nitride (WNₓ) substrate, a boron (B) monolayer on the W monolayer, and a bulk W layer on the B monolayer.

### TECHNICAL FIELD

The present disclosure relates generally to memory devices and, more particularly, to memory devices with tungsten digitlines.

### BACKGROUND

Many electronic devices and systems include integrated circuits for the storage of data during the operation of the devices. For example, electronic devices such as computers, printing devices, scanning devices, personal digital assistants, calculators, computer work stations, audio and/or video devices, communications devices such as cellular telephones, and routers for packet switched networks may include memory in the form of integrated circuits for retaining data as part of their operation. Advantages of using integrated circuit memory compared to other forms of memory include space conservation and miniaturization, conserving limited battery resources, decreasing access time to data stored in the memory, and cutting the costs of assembling the electronic devices.

Dynamic Random Access Memory (DRAM) is an example of integrated circuit memory. DRAM typically comprises an array of semiconductor capacitor cells, each of which may hold an amount of electric charge that represents the logical value of a stored bit. The cells in the array are typically arranged in rows and columns. Each cell is situated at the intersection of a row and a column. Each cell in the DRAM array may be accessed by simultaneously addressing the intersecting row and column.

In operation, internal amplifiers in the DRAM sense the amounts of electric charges stored on the capacitors. Based on the sensed electric charges, the outputs of the sense amplifiers represent the logical values of the bits that are stored in the DRAM array. In this manner, the data stored in the array may be extracted from the DRAM integrated circuit for use by other integrated circuits in the electronic device. In addition, other internal circuitry on the DRAM refreshes the charge on those cells that the sense amplifiers have determined to already hold an electric charge. In this manner, the DRAM compensates for leakages of electric charge from the semiconductor capacitor cells, such as leakage into the substrate of the DRAM integrated circuit. Such reading, writing, and maintaining of charge on the cells are substantial internal operations of the DRAM.

The sense amplifiers connect to the cells through digitlines, which comprise the columns of the DRAM. Before reading from a cell, the DRAM removes residual charge on the digitline that addresses the cell. The residual charge is left over from a previous reading of another cell that shares the same digitline. The DRAM equalizes the digitline by pre-charging the digitline to a common potential before reading from the cell. When the DRAM addresses the cell, the charge stored in the cell raises or lowers the potential of the digitline from the common potential, signifying the logic value of the bit stored in the cell.

Digitlines, however, have internal resistance, internal parasitic capacitance, and parasitic capacitance with other digitlines. The resistances and capacitances comprise an RC circuit whose time constant increases the equalization time for pre-charging the digitlines. If too large, the time constant results in a slower read time for the DRAM integrated circuit that limits the use of the DRAM integrated circuit in modern high-speed electronic devices. As clock speeds for DRAM integrated circuits increase, the minimum time between commands lessens and the equalization times for digitlines should likewise decrease.

Decreasing bitline resistance/capacitance can improve write and read performance and failure rates. The capacitance can be decreased by reducing the bitline thickness. However, a decrease in the line thickness below 1000 angstroms (Å) significantly increases its electrical resistivity, resulting in a degradation of the device performance.

### BRIEF DESCRIPTION OF THE DRAWINGS

FIG. 1 illustrates a DRAM memory cell including a digitline and wordline connected to the memory cell.

FIG. 2 illustrates a DRAM memory array including digitlines and wordlines connected to each memory cell in the memory array.

FIGS. 3A-3B illustrate a cross sectional view of a digitline fabricated according to a previous approach.

FIGS. 4A-4C illustrate a cross sectional view of a digitline fabricated according to an embodiment of the present disclosure.

FIG. 5 illustrates the grain structure of tungsten on a digitline fabricated according to a previous approach.

FIG. 6 illustrates a cross-sectional view of a digitline showing the grain structure of a digitline fabricated according to a previous approach.

FIG. 7 illustrates the grain structure of tungsten on a digitline fabricated in accordance with an embodiment of the present disclosure.

FIG. 8 illustrates a cross-sectional view of a digitline showing the grain structure of a digitline fabricated in accordance with an embodiment of the present disclosure.

FIG. 9 is a functional block diagram of an electronic memory system having at least one memory device including a digitline formed according to an embodiment of the present disclosure.

FIG. 10 is a functional block diagram of a memory module having at least one memory device including a digitline formed according to an embodiment of the present disclosure.

### DETAILED DESCRIPTION

Embodiments of the present disclosure include systems, methods, and devices having tungsten digitlines. One method embodiment includes forming tungsten digitlines with a tungsten (W) monolayer on a tungsten nitride (WNₓ) substrate, forming a boron (B) monolayer on the W monolayer, and forming a bulk W layer on the B monolayer.

In some embodiments, the monolayer of tungsten (W) can be grown using one cycle of diborane (B₂H₆) followed by hydrogen (H₂) reduction of tungsten hexafluoride (WF₆). This step can promote adhesion of the bulk tungsten layer to the structure. In various embodiments, the deposition of a monolayer of boron can be performed by thermal decomposition of B₂H₆ at a high temperature. Boron acts as a surfactant and acts to facilitate the formation of the grain-structure in the bulk tungsten layer. However, a large amount of boron can reduce the adhesion of tungsten. In various embodiments, a low-resistivity and conformal bulk tungsten layer can be grown by chemical vapor deposition (CVD) using H₂ reduction of WF₆.

The achieved grain-structure of the bulk tungsten layer reduces the resistivity in the digitline. According to embodiments of the present disclosure, the grain structure using the CVD process to grow the bulk tungsten layer with H₂ reduction of WF₆ creates grains that are 1000-6000 angstroms (Å) in width on a bulk tungsten layer that is less than 500 angstroms (Å) thick. These dimensions are 4-5 times larger than that achievable by previous tungsten deposition processes. This increase in the grain structure results in a decrease in resistivity in the digitline of over 10 μOhm·cm. This decrease reduces the resistivity by half over the resistivity of previous tungsten deposition processes.

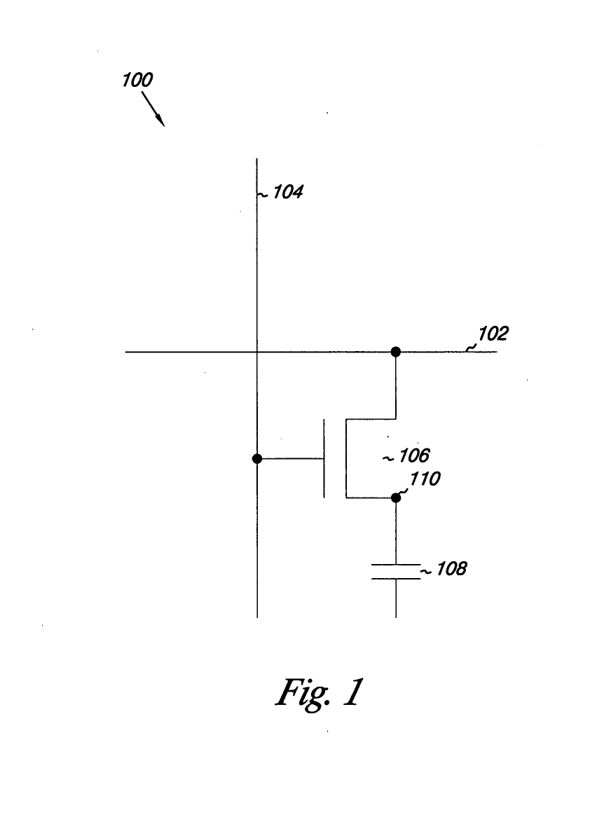

FIG. 1 illustrates a DRAM memory cell including a digitline and wordline connected to the memory cell. The DRAM memory cell shown in FIG. 1 consists of a transistor 106 and a capacitor 108, referred to as a one-transistor one-capacitor (1T1C) cell. The wordline 104 is connected to the gate of the transistor 106 and the digitline 102 is connected to the source/drain side of the transistor 106. The transistor 106 operates as a switch, between the capacitor 108 and the digitline 102. The memory cell is capable of holding a single piece of binary information, as stored electric charge in the cell capacitor 108. Embodiments are not so limited to the example memory cell of FIG. 1. For example, in some embodiments, the memory cell 100 can be a multilevel cell. Given a bias voltage of Vcc/2 on the capacitor's common node 110, a logic one level is represented by +Vcc/2 volts across the capacitor and a logic zero is represented by −Vcc/2 volts across the capacitor 108. In either case, the amount of charge stored in the capacitor is Q=C·VCC/2 coulombs, where C is the capacitance value in Farads.

The wordline 104, connected to the gate of the transistor 106, is used to activate the memory cell. The memory cell 100 is addressed at an intersection of wordline 104 and digitline 102. The state of the memory cells is then read by a sense amplifier (not shown) that determines through digitline 102 the state of the cell 100. A potential is provided to digitline 102 as part of a refresh operation to refresh the state read from the memory cell. A DRAM memory cell constantly needs to be refreshed because the capacitor 108 in the memory cell 100 continuously is losing its charge. A typical memory cell needs to be refreshed at a minimum of once every several nanoseconds.

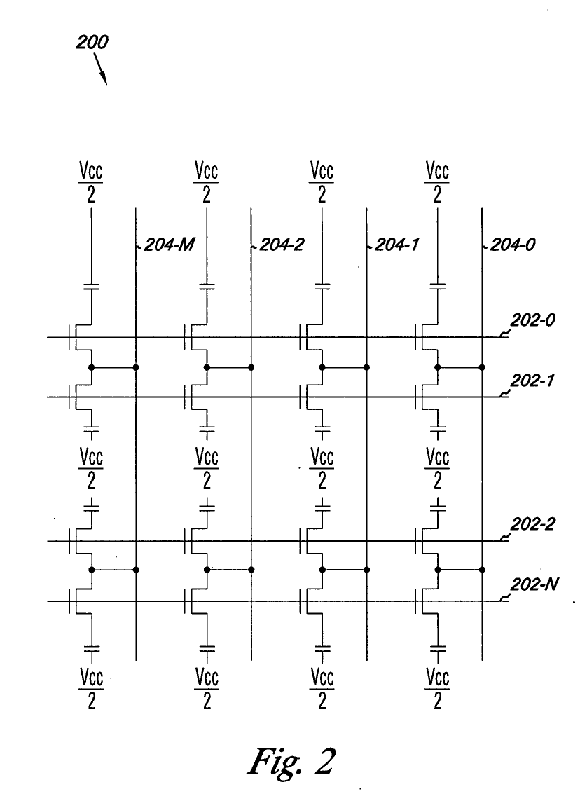

FIG. 2 illustrates a DRAM memory array including digitlines and wordlines connected to each memory cell in the memory array. FIG. 2, shows a DRAM memory array 200 including digitlines, 204-0, . . . , 204-M, and wordlines, 202-0, . . . , 202-N, connected to each memory cell in the memory array. A DRAM memory array consists of a series of memory cells connected at contact points to wordlines and digitlines. The digitlines, 204-0, . . . , 204-M, in FIG. 2, connect to the memory cells in the memory array. The memory array in FIG. 2 is created by tiling a selected quantity of memory cells together such that memory cells along a given digitline do not share a common wordline and such that memory cells along a common wordline do not share a common digitline. The memory cell transistor 106 gate terminal connects to a wordline 202-0, . . . , 202-N. The wordline, which connects to a multitude of memory cells, consists of an extended segment of the same material used to form the transistor's gate. The wordline is physically orthogonal to the digitline.

The digitlines 204-0, . . . , 204-M consist of a conductive line connected to a memory cell's transistors. Due to the large number of attached memory cells, physical length of given digitline, and the digitline's proximity to other features, the digitline can be susceptive to large capacitive coupling. For instance, a typical value for digitline capacitance on a 350 nanometer (nm) scale fabrication process might be around 300 femtofarads (fF).

Digitline capacitance is an important parameter in memory cells since it dictates many other aspects of the design. A low capacitance in the digitline is desired for improved performance in a memory cell. Low capacitance in the digitline improves read and write times in the memory cell and decreases the amount of read and write failure in the memory cell. The digitline capacitance can be lowered by decreasing the thickness of the digitline. In reducing the thickness of the digitline, the capacitance in not only decreased in a beneficial manner, but also the physical size the memory array can be reduced allowing for more dense memory arrays.

A side effect of decreasing the digitline thickness to reduce capacitance in the digitline and in turn improve the performance characteristics of the memory cell is an increase in digitline resistivity. When the digitline thickness is reduced, the resistivity in the digitline also increases. An increase in resistivity causes degradation in the memory cell performance. Therefore, there is a limit to the amount that the digitline thickness can be reduced.

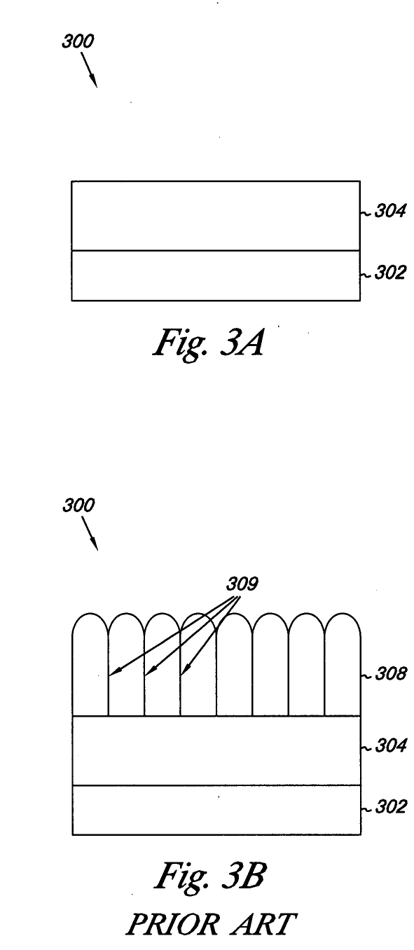

FIGS. 3A-3B illustrate a cross sectional view of a digitline fabricated according to a previous approach. As shown in FIG. 3A, a digitline 300 is formed on a tungsten nitride (WNₓ) substrate 302. A tungsten layer 304 is formed on the WNₓ substrate 302. In previous approaches, the tungsten layer 304 is at least 50 Å thick and is formed by SiH₄ reduction of tungsten hexafluoride (WF₆) at a temperature in the range of 350° C. to 450° C. The next step is to form a bulk layer of tungsten 308 on tungsten layer 304.

FIG. 3B illustrates that the bulk layer of tungsten 308 is formed by hydrogen (H₂) reduction of WF₆ at a temperature in the range of 350° C. to 450° C. As shown in FIG. 3B, this method of forming the tungsten digitline 300 creates a grain structure in the bulk tungsten layer 308 with fine grains as illustrated by the arrows 309 pointing to the closely spaced geometry of the vertical grain boundaries within the bulk tungsten layer 308. The fine grains in the bulk tungsten layer 308 increases the resistance in the digitline 300. The resistance in the digitline 300 with the grain structure of the bulk tungsten layer 308 results in decrease performance characteristics in DRAM memory cells when the digitline 300 thickness is below 500 Å. A thickness of less than 500 Å is desirable because of the reduction in capacitance in the digitline 300 associated with a reduction in digitline thickness.

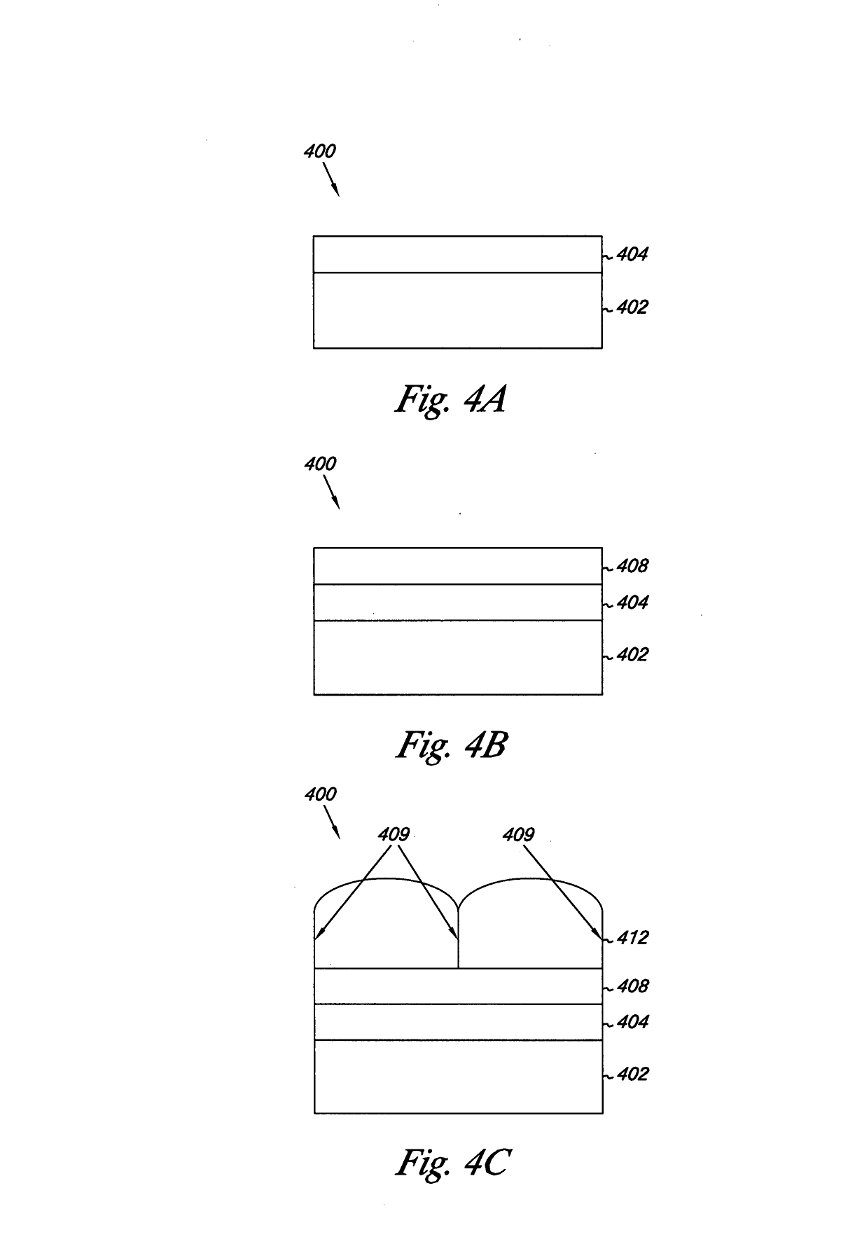

FIGS. 4A-4C illustrate a cross sectional view of a digitline fabricated according to an embodiment of the present disclosure. FIG. 4A illustrates a cross sectional view of a partial tungsten digitline 400 after a process step according to an embodiment of the present disclosure. The process begins with a tungsten nitride (WNₓ) substrate 402. As shown in FIG. 4A, a monolayer of tungsten 404 film is formed on the WNₓ substrate 402. The tungsten monolayer 404 is formed using one cycle of B₂H₆ followed by H₂ reduction of WF₆ at a temperature in the range of 250° C. to 450° C. The tungsten monolayer is formed to a thickness in range of 1 Å to 10 anstroms. It is difficult to nucleate the bulk tungsten layer and the tungsten monolayer 404 is formed to promote the adhesion of bulk tungsten layer. Embodiments are not limited to particular layer and monolayer thicknesses.

As shown in FIG. 4B, a monolayer of Boron (B) 408 can be formed on the tungsten monolayer 404. FIG. 4B thus illustrates a cross sectional view of a partial tungsten digitline 400 after the second process step. The monolayer of B 408 can be formed on the tungsten monolayer 404 by thermal decomposition of B₂H₆ at a temperature in the range of about 350° C. to 450° C. The thermal decompostion of B₂H₆ to form the B monolayer takes place for a time period ranging from about 1 second to 20 seconds. The boron monolayer is formed to a thickness in the range of 1 Å 10 Å.

FIG. 4C illustrates a cross sectional view of a tungsten digitline 400 after a subsequent process step. In this next process step, a bulk tungsten layer 412 is formed on the boron monolayer 408. Boron acts as a surfactant and acts to facilitate the formation of the grain-structure in the bulk tungsten layer 412. However, a large amount of boron can reduce the adhesion of tungsten, therefore only a monolayer of boron is formed on the tungsten monolayer 404. The amount of boron in the boron monolayer 408 is in the range of about 2% to 20% of the amount of tungsten in the bulk tungsten layer 412. The bulk tungsten layer 412 is formed by H₂ reduction of WF₆ at a temperature in the range of about 350° C. to 450° C. In some embodiments, the bulk tungsten layer 412 is formed by H₂ reduction of WF₆ at a temperature of approximately 400° C. The bulk tungsten layer 412 in FIG. 4C formed to a thickness of less than 500 Å. Forming the bulk tungsten layer to a thickness of less than 500 Å further helps to maintain a low capacitance in the tungsten digitline 400. In FIG. 4C, the bulk tungsten layer 412 has a relatively large grain size as illustrated by arrows 409 pointing to the more widely space geometry of the vertical grain boundaries within the bulk tungsten layer 412 as compared to the vertical grain boundary spacing shown previously in FIG. 3B. The more widely spaced geometry of the vertical grain boundaries is intended to represent the relatively larger grain size of the bulk tungsten layer 412 relative to the finer grain boundaries shown in FIG. 3B. The larger grain size of the bulk tungsten layer 412 helps to reduce the resistance in the tungsten digitline 400 despite its thickness being less than 500 Å. Previously, it was not possible to achieve such large grain boundaries because of the difficulty of having to nucleate tungsten on the tungsten nitride layer in the previous approaches. Embodiments of the digitline are not limited to particular layer and monolayer thicknesses.

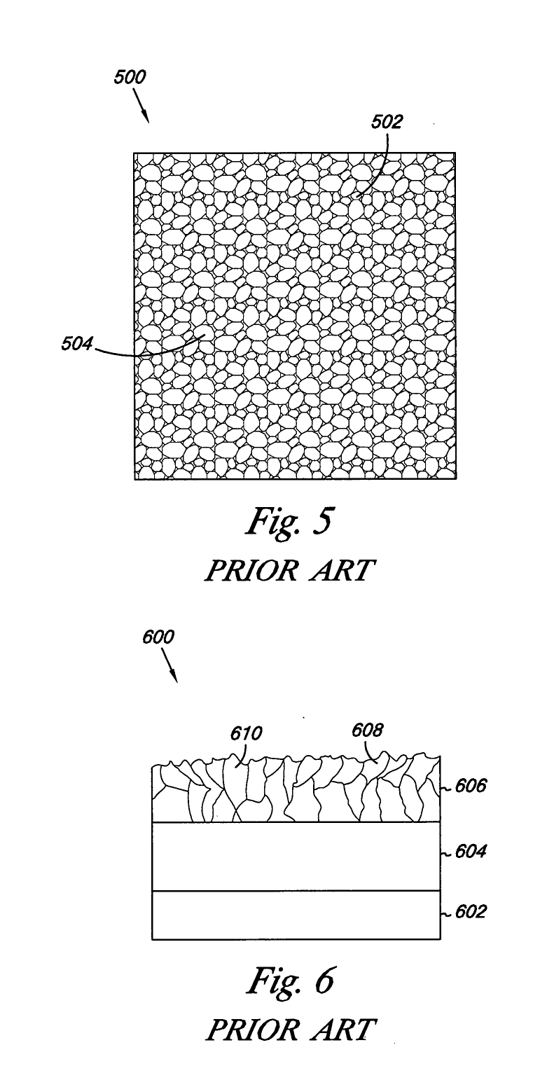

FIGS. 5 and 6 illustrate the grain structure of tungsten on a digitline fabricated according to a previous approach, as described in association with FIGS. 3A and 3B. FIG. 5 illustrates a top view of a bulk tungsten layer 500 magnified to a scale of 500 nm/inch. The bulk tungsten layer 500 has grains range from 300 Å to 800 Å in width. The relatively small grain structure in the bulk tungsten layer results in a center resistivity of approximately 20 μOhm·cm for a digitline 520 Å thick. Tungsten grains 502 and 504 illustrate the various grain sizes of the tungsten formed using the previous approaches of FIGS. 3A and 3B. Tungsten grain 502 has a width of approximately 350 Å and tungsten grain 504 has a width of approximately 800 Å.

FIG. 6 shows a cross sectional view of a tungsten digitline 600 magnified to a scale of 500 nm/inch. This view of the digitline illustrates the small grain structure in the bulk tungsten layer 606 of the tungsten digitline 600. The small grains structure increases the resistance in the tungsten digitline 600 due to the difficulty caused by the current having to pass through the large number of boundaries of the grains. With a desired digitline thickness of less than 500 Å, the grain size of the bulk tungsten layer formed using the method described in FIGS. 3A and 3B results in grains of approximately 400 Å in width with a corresponding center resistivity of 20 μOhm·cm.

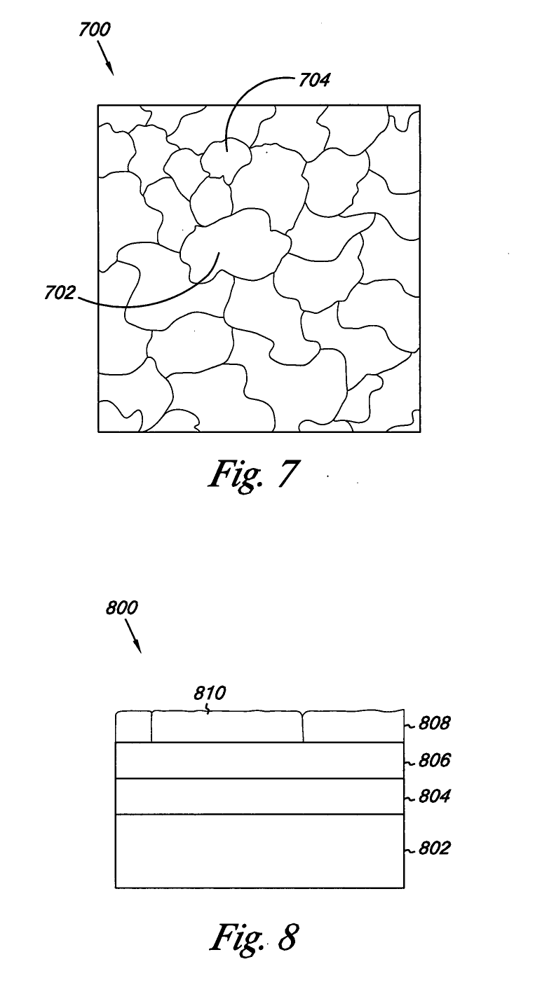

FIG. 7 illustrates the grain structure of tungsten on a digitline fabricated in accordance with an embodiment of the present disclosure. FIG. 7 shows a top view of a bulk tungsten layer 700 magnified to a scale of 500 nm/inch. The bulk tungsten layer 700 has grains which range from approximately 1000 Å to 6000 Å in width. The large grains of the bulk tungsten layer 700 in the digitline have a center resistance in the range of approximately 9 μOhm·cm to 11 μOhm·cm for a digitline 300-500 Å thick. Tungsten grains 702 and 704 illustrate the various grain sizes of the bulk tungsten layer 700 according to the process described in FIGS. 4A-4C. Tungsten grain 702 has a width of approximately 5000 Å and tungsten grain 704 has a width of approximately 1300 Å.

FIG. 8 illustrates a cross-sectional view of a digitline showing the grain structure of a digitline fabricated in accordance with an embodiment of the present disclosure magnified to a scale of 500 nm/inch. As can be observed in the cross sectional view of FIG. 8, the grain boundaries are more widely spaced as compared to the grain boundaries shown in the cross sectional view of FIG. 6. The more widely spaced grain boundaries are intended to further illustrate the larger grain size to the bulk tungsten layer 808 formed according to a process embodiment of the present disclosure. The large grain structure decreases the resistance in the tungsten digitline 800 due to the increased ease in which the current passes through a small number of grain boundaries. With a desired digitline thickness of less than 500 Å, the grain size of the bulk tungsten layer 800 formed according to a process embodiment results in grains ranging from 1000 Å to 6000 Å in width. These grains have a cross sectional width corresponding to a center resistivity of approximately 10 Ohm·cm.

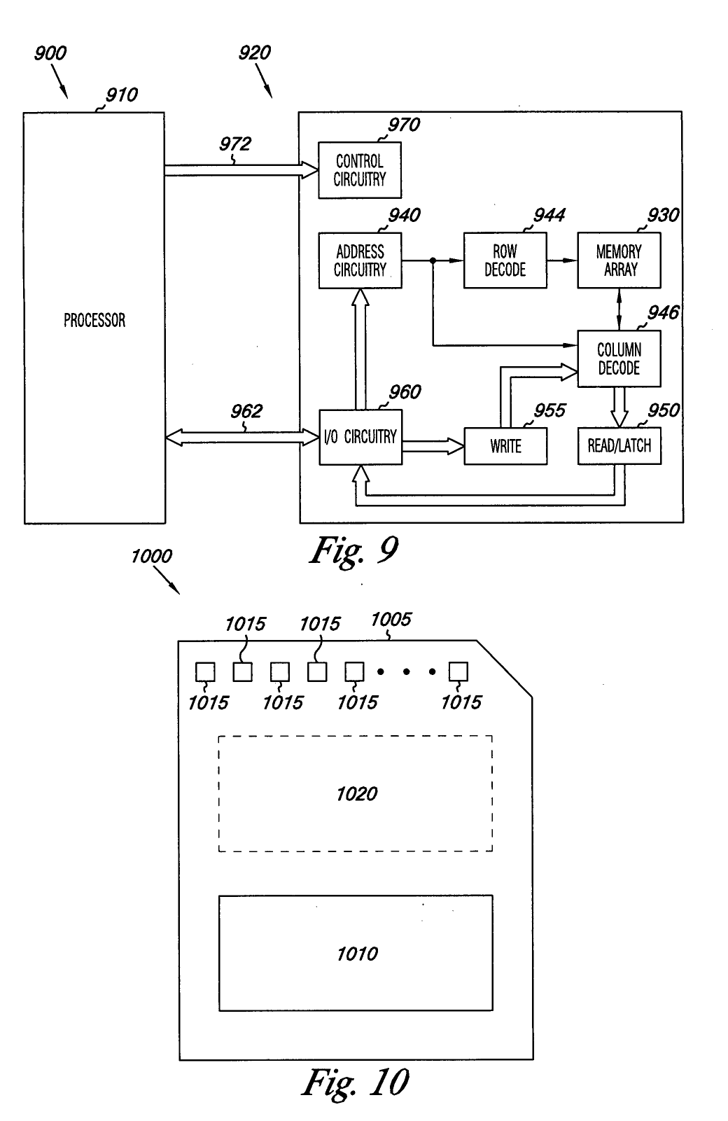

FIG. 9 is a functional block diagram of an electronic memory system 900 having at least one memory device 920 including a digitline formed according to an embodiment of the present disclosure, e.g., the process described in FIGS. 4A-4C. Memory system 900 includes a processor 910 coupled to a DRAM memory device 920 that includes a memory array 930 of memory cells. The memory system 900 can include separate integrated circuits or both the processor 910 and the memory device 920 can be on the same integrated circuit. The processor 910 can be a microprocessor or some other type of controlling circuitry such as an application-specific integrated circuit (ASIC).

For clarity, the electronic memory system 900 has been simplified to focus on features with particular relevance to the present disclosure. The memory device 920 includes an array of DRAM memory cells 930. The control gates of each row of memory cells are coupled with a word line, while the drain regions of the memory cells are coupled to digitlines. As will be appreciated by those of ordinary skill in the art, the manner of connection of the memory cells to the wordlines and digitlines lines depends on the array architecture.

The embodiment of FIG. 9 includes address circuitry 940 to latch address signals provided over I/O connections 962 through I/O circuitry 960. Address signals are received and decoded by a row decoder 944 and a column decoder 946 to access the memory array 930. In light of the present disclosure, it will be appreciated by those skilled in the art that the number of address input connections depends on the density and architecture of the memory array 930 and that the number of addresses increases with both increased numbers of memory cells and increased numbers of memory blocks and arrays.

The memory array 930 of memory cells can include tungsten digitlines formed according to embodiments described herein. The memory device 920 reads data in the memory array 930 by sensing voltage and/or current changes in the memory array columns using sense/buffer circuitry that in this embodiment can be read/latch circuitry 950. The read/latch circuitry 950 can be coupled to read and latch a row of data from the memory array 930. I/O circuitry 960 is included for bi-directional data communication over the I/O connections 962 with the processor 910. Write circuitry 955 is included to write data to the memory array 930.

Control circuitry 970 decodes signals provided by control connections 972 from the processor 910. These signals can include chip signals, write enable signals, and address latch signals that are used to control the operations on the memory array 930; including data read, data write, data refresh, and data erase operations. In various embodiments, the control circuitry 970 is responsible for executing instructions from the processor 910 to perform the operating and programming embodiments of the present disclosure. The control circuitry 970 can be a state machine, a sequencer, or some other type of controller. It will be appreciated by those skilled in the art that additional circuitry and control signals can be provided, and that the memory device detail of FIG. 9 has been reduced to facilitate ease of illustration.

FIG. 10 is a functional block diagram of a memory module 1000 having at least one memory device 1010 including a digitline formed according to an embodiment of the present disclosure, e.g. the process described in FIGS. 4A-4C. Memory module 1000 is illustrated as a DRAM chip, but other types of memory and are intended to be within the scope of “memory module” as used herein. In addition, although one example form factor is depicted in FIG. 10, these concepts are applicable to other form factors as well.

In some embodiments, memory module 1000 will include a housing 1005 (as depicted) to enclose one or more memory devices 1010, though such a housing is not essential to all devices or device applications. At least one memory device 1010 includes an array of memory cells with a tungsten digitline formed according to embodiments described herein. Where present, the housing 1005 includes one or more contacts 1015 for communication with a host device. Examples of host devices include digital cameras, digital recording and playback devices, PDAs, personal computers, memory card readers, interface hubs and the like. For some embodiments, the contacts 1015 are in the form of a standardized interface. In general, however, contacts 1015 provide an interface for passing control, address and/or data signals between the memory module 1000 and a host having compatible receptors for the contacts 1015.

The memory module 1000 may optionally include additional circuitry 1020, which may be one or more integrated circuits and/or discrete components. For some embodiments, the additional circuitry 1020 may include a memory controller for controlling access across multiple memory devices 1010 and/or for providing a translation layer between an external host and a memory device 1010. For example, there may not be a one-to-one correspondence between the number of contacts 1015 and a number of 1010 connections to the one or more memory devices 1010. Thus, a memory controller could selectively couple an I/O connection (not shown in FIG. 10) of a memory device 1010 to receive the appropriate signal at the appropriate I/O connection at the appropriate time or to provide the appropriate signal at the appropriate contact 1015 at the appropriate time. Similarly, the communication protocol between a host and the memory module 1000 may be different than what is required for access of a memory device 1010. A memory controller could then translate the command sequences received from a host into the appropriate command sequences to achieve the desired access to the memory device 1010. Such translation may further include changes in signal voltage levels in addition to command sequences.

The additional circuitry 1020 may further include functionality unrelated to control of a memory device 1010 such as logic functions as might be performed by an ASIC. Also, the additional circuitry 1020 may include circuitry to restrict read or write access to the memory module 1000, such as password protection, biometrics or the like. The additional circuitry 1020 may include circuitry to indicate a status of the memory module 1000. For example, the additional circuitry 1020 may include functionality to determine whether power is being supplied to the memory module 1000 and whether the memory module 1000 is currently being accessed, and to display an indication of its status, such as a solid light while powered and a flashing light while being accessed. The additional circuitry 1020 may further include passive devices, such as decoupling capacitors to help regulate power requirements within the memory module 1000.

For the reasons stated above, and for other reasons stated below which will become apparent to those skilled in the art upon reading and understanding the present specification, there is a need in the art for a digitline that is thin enough to lower the capacitance in the digitline for performance enhancement while maintaining a low resistivity in the digitline. To meet this objective, the digitline needs to have a grain structure that is large enough to reduce the impedance of the current flow through the tungsten digitline.

### Conclusion

Methods, devices, and systems for using and forming tungsten digitlines have been described. The tungsten digitlines formed according to embodiments of the present disclosure can be formed with a tungsten (W) monolayer on a tungsten nitride (WNₓ) substrate, a boron (B) monolayer on the W monolayer, and a bulk W layer on the B monolayer.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method for forming a digitline in a memory cell, comprising:
forming a tungsten (W) monolayer on a tungsten nitride (WNₓ) substrate;
forming a boron (B) monolayer on the W monolayer; and
forming a bulk W layer on the B monolayer.

2. The method of claim 1, wherein the method includes forming the W monolayer using one cycle of diborane (B₂H₆) followed by hydrogen (H₂) reduction of tungsten hexafluoride (WF₆).

3. The method of claim 1, wherein the method includes forming the W monolayer at a thickness between 1 angstrom (Å) and 10 angstroms (Å).

4. The method of claim 1, wherein the method includes forming the B monolayer by thermal decomposition of B₂H₆ at a temperature between 350° C.-450° C.

5. The method of claim 4, wherein the method includes forming the B monolayer by thermal decomposition of B₂H₆ for a time period ranging from 1 second to 20 seconds.

6. The method of claim 1, wherein the method includes forming the B monolayer at a thickness between 1 Å and 10 Å.

7. The method of claim 1, wherein the method includes forming the bulk W layer by chemical vapor deposition (CVD) using H₂ reduction of WF₆.

8. The method of claim 1, wherein the method includes forming a digitline with the amount of boron in the boron monolayer in the range of 2% to 20% of the amount of tungsten in the bulk tungsten layer.

9. The method of claim 1, wherein the method includes forming the bulk W layer with a grain size between 1000 anstroms and 6000 angstroms in width.

10. The method of claim 1, wherein the method includes forming a digitline in a memory cell with a thickness of less than 500 Å.

11. The method of claim 1, wherein the method includes forming a digitline in a memory cell with a center resistance between 9 μOhm·cm and 11 μOhm·cm.

12. A memory device, comprising:
a number of wordlines;
a number of digitlines formed from a tungsten monolayer, a boron monolayer, and a bulk tungsten layer;
wherein each wordline and digitline is connected to a memory cell, and wherein the memory cell is comprised of a capacitor and a transistor.

13. The memory device of claim 12 wherein the digitline is connected to a drain side of a transistor associated with the memory cell.

14. The memory device of claim 12, wherein the wordline is connected to a gate side of a transistor associated with the memory cell.

15. The memory device of claim 12, wherein the W monolayer is less than 10 anstroms thick.

16. The memory device of claim 12, wherein the B monolayer is less than 10 ansgroms thick.

17. The memory device of claim 12, wherein the bulk W layer is less than 500 Å thick.

18. The memory device of claim 12, wherein the bulk W layer has a grain structure with grains between 1000 Å and 6000 Å wide.

19. A memory device comprising:
an array of memory cells arranged in rows coupled by wordlines and columns coupled by bitlines,
wherein the digitlines are formed of a tungsten monolayer, a boron monolayer, and a bulk tungsten layer; and
circuitry for control and access to the array of memory cells.

20. The memory device of claim 19, wherein the circuitry has address signals that are received and decoded by a row decoder and a column decoder to access the array of memory cells.

21. The memory device of claim 19, wherein additional circuitry includes a memory controller for controlling access across multiple memory devices.

22. The memory device of claim 19, wherein the W monolayer is less than 10 Å thick.

23. The memory device of claim 19, wherein the B monolayer is less than 10 Å thick.

24. The memory device of claim 19, wherein the bulk W layer is less than 500 Å thick.

25. The memory device of claim 19, wherein the bulk W layer has a grain structure with grains between 1000 Å and 6000 Å wide.

26. A method of operating a digitline, comprising:
addressing a memory cell at an intersection of a wordline and a digitline formed of a tungsten (W) monolayer on a tungsten nitride (WNₓ) substrate, a boron (B) monolayer on the W monolayer, and a bulk W layer on the B monolayer;
reading the digitline using a sense amplifier;
providing a potential to the digitline as part of a refresh operation to refresh a state read from the memory cell.

27. The method of claim 26, wherein the refresh operation includes rewriting the memory cell state at rate of once every 1 nanoseconds to 100 nanoseconds.

28. The method of claim 26, wherein the method includes forming the W monolayer using one cycle of B₂H₆ followed by H₂ reduction of WF₆.

29. The method of claim 26, wherein the W monolayer is less than 10 Å thick.

30. The method of claim 26, wherein the B monolayer is less than 10 Å thick.

31. The method of claim 26, wherein the bulk W layer is less than 500 Å thick.

32. The method of claim 26, wherein the bulk W layer has a grain structure with grains between 1000 Å and 6000 Å wide.
